(19) United States
(12) Patent Application Publication
(10) Pub. No.: US 2025/0113629 A1
(43) Pub. Date: Apr. 3, 2025

(54) IMAGE SENSOR CHARGE DIRECTION STRUCTURES AND METHODS

(71) Applicant: SEMICONDUCTOR COMPONENTS INDUSTRIES, LLC, Scottsdale, AZ (US)

(72) Inventor: Jon DALEY, Boise, ID (US)

(73) Assignee: SEMICONDUCTOR COMPONENTS INDUSTRIES, LLC, Scottsdale, AZ (US)

(21) Appl. No.: 18/479,316

(22) Filed: Oct. 2, 2023

(51) Int. Cl. H01L 27/146; H05F 3/02; H05F 3/04

(52) U.S. Cl. CPC H10F 39/18; H05F 3/02; H05F 3/04; H10F 39/199

(57) ABSTRACT

A static charge handling system may include an array of photodiodes, a metal grid coupled to the array of photodiodes, and a set of metal projections extending away from the metal grid. The set of metal projections may be configured to direct charge from one of electrostatic discharge or static charge into the metal grid.

### BACKGROUND

### 1. Technical Field

Aspects of this document relate generally to image sensor devices, such as devices for observing electromagnetic radiation.

### 2. Background

Packages for semiconductor devices have been devised that allow for electrical signal routing from a semiconductor die to a circuit board or motherboard to which the package is coupled. Various semiconductor packages have been developed that protect the semiconductor die from humidity or mechanical stress.

### SUMMARY

A static charge handling system may include an array of photodiodes, a metal grid coupled to the array of photodiodes, and a set of metal projections extending away from the metal grid. The set of metal projections may be configured to direct charge from one of electrostatic discharge or static charge into the metal grid.

Implementations of an static charge handling system may include one, all, or any of the following:

The set of metal projections may be located on a side of the metal grid opposite the array of photodiodes.

The set of metal projections may be each located at a set of intersections of the metal grid.

The set of metal projections may be in a layer of passivation material coupled to the metal grid.

The array of photodiodes may be included in a backside illumination sensor.

The set of metal projections may include one of a rectangular prism, a cylinder, or a triangular prism.

The set of metal projections may include one of a square based cone, a triangle based cone, a cone, or a conical frustum.

Implementations of a static charge handling system may include an array of photodiodes, a metal grid coupled on a first side of the array of photodiodes, and a set of metal projections coupled on a side of the metal grid opposite the first side of the array of photodiodes and extending away from the metal grid.

Implementations of an static charge handling system may include one, all, or any of the following:

The set of metal projections may be each located at a set of intersections of the metal grid.

The set of metal projections may be each located along the metal grid.

The set of metal projections may be in a layer of passivation material coupled to the side of the metal grid opposite the first side of the array of photodiodes.

The array of photodiodes may be included in a backside illumination sensor.

The set of metal projections may include one of a rectangular prism, a cylinder, or a triangular prism.

The set of metal projections may include one of a square based cone, a triangle based cone, a cone, or a conical frustum.

Implementations of a method of handing charge may include providing an array of photodiodes with a first side to which a metal grid may be coupled and a set of metal projections coupled to the metal grid on a side of the metal grid opposite the first side of the array of photodiodes and extending away from the metal grid and receiving electric charge into the set of metal projections. The method may also include directing the electric charge into the metal grid.

Implementations of a method of handing charge may include one, all, or any of the following:

The method may include where the metal grid is grounded and further include directing the electric charge to ground using the metal grid.

Receiving electric charge further may include receiving electric charge from a passivation layer.

The set of metal projections may be formed in a passivation layer.

The electric charge may be from one of electrostatic discharge events or static electricity.

The array of photodiodes may be included in a backside illumination sensor.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a top down view of an implementation of a metal grid over an array of photodiodes;

FIG. 2 is a cross sectional view of a first implementation of a metal grid and metal projections and of a second implementation of a metal grid and metal projections; and

FIG. 3 is a table illustrating various shapes of various implementations of metal projections.

### DESCRIPTION

This disclosure, its aspects and implementations, are not limited to the specific components, assembly procedures or method elements disclosed herein. Many additional components, assembly procedures and/or method elements known in the art consistent with the intended image sensor charge direction structures and methods will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such image sensor charge direction structures, and implementing components and methods, consistent with the intended operation and methods.

Image sensor devices can exhibit image artifacts resulting from electric charge creating an electrical field that breaks down electrical isolation between individual pixels in a pixel array (array of photodiodes) that causes “charge sharing” in clusters of pixels. In the image produced by an image sensor device, these image artifacts can take on the appearance of water-drop or blob looking defects in the image. In some implementations, the electric charge results from an electrostatic discharge (ESD) event that traps electric charge in a layer of passivation material included in the image sensor device, particularly in the back side of the image sensor device. In other implementations, the electric charge may be static charge that has accumulated on the image sensor device/back side of the image sensor device.

This image artifact effect due to charge storage has been observed to occur where the array of photodiodes is included in a backside illumination (BSI) sensor. However, the ability for electric charge to create image artifacts using this mechanism can occur in a wide variety of image sensor types.

In various image sensor systems, a grid of metal material (metal grid) is used to help handle electrical charge that builds up on the array of photodiodes that form the pixel array of an image sensor device. The metal grid can be coupled to a side of the array of photodiodes. Some image sensor implementations, the metal grid is coupled to a lower side of the array of photodiodes, or a side of the array of photodiodes opposite where other devices like microlenses, color filter arrays, or an optically transmissive cover are adjacent to or coupled to the array of photodiodes. In other implementations, however, the metal grid may be coupled to the side of the array of photodiodes which faces/faces into the image sensor device itself. In some implementations, the metal grid is attached to an electrical ground (grounded); in other implementations, the metal grid is electrically free floating relative to ground. It has been observed that the metal grid, standing alone, does help reduce image artifacts due to electric charge, but does not eliminate them in certain situations and/or for certain image sensor device types due to the inability of the electric charges to reach the metal grid from the materials surrounding the metal grid/array of photodiodes.

Referring to FIG. 1, a portion of an implementation of an image sensor 2 is illustrated that includes an array of photodiodes (pixel array) 4 over which a metal grid 6 is coupled. It must be understood that FIG. 1 illustrates only a small portion of the array of photodiodes and so the structure of the metal grid 6 is repeated across the entire, a substantial majority, a majority, or a portion of the array of photodiodes 4. While the portions of the metal grid are illustrated in FIG. 1 as being in the same layer, in some implementations, the metal grid may include components that physically cross each other while being held in/remaining in electrical contact with each other. Illustrated in FIG. 1 are a set of metal projections 8 that extend upwardly out of the paper. The metal projections 8 collect and direct electric charge into the metal grid 6 during operation of the image sensor device. As previously discussed, the electric charges collected by the metal projections 8 may come from electric charges from an ESD event and/or may be static charge that has accumulated on/in the array of photodiodes. In this way, the charge collecting and directing operation of the metal projections 8 can be analogized to the operation of lightning rods albeit on a microscopic scale. However, the operation of the metal projections 8 and lightning rods differ in an important respect in that lighting rods are designed to both receive charge from lighting and act as point sources releasing ionized molecules into ambient air during a thunderstorm to help reduce the odds of a lightning strike actually occurring during a thunderstorm. In contrast, the metal projections 8 work to collect electric charge and direct it down into the metal grid and so specifically do not release any electric charge during operation of the image sensor device.

In the implementation illustrated in FIG. 1, each of the set of metal projections 8 in this implementation is illustrated as being located at an intersection 10 of the metal grid 6. In this implementation, each intersection 10 includes a metal projection 8 coupled thereto. In other implementations, the ratio of metal projections to intersections may be less than 1:1, such as, by non-limiting example, 1:2, 1:3, 1:5, 1:10, or another desired ratio designed to deliver a certain/desired/needed electric charge handling effect. The ratio may be achieved in a wide variety of ways as well, where for a ratio of 1:2, a metal projection 8 is coupled at every other intersection 10 or in a pattern of having a metal projections coupled in two adjacent intersections 10 followed by skipping two adjacent intersections. A wide variety of patterns or even random patterns of locating metal projections in intersections may be employed in various system implementations.

While the implementation illustrated in FIG. 1 shows each of the set of metal projections 8 located at an intersection 10 of the metal grid 6, in other implementations, the metal projections may be located at other locations along the metal grid, such as along either or both sets of crossing metal traces that form the metal grid 6. In this way, the set of metal projections is located along the metal grid rather than being located at the intersections of the metal grid. In these implementations, concentrations of metal projections at certain locations on the pixel array/array of photodiodes may be employed to help with distributing charge away from known particularly electric static charge sensitive locations on the device. The use of concentrations of the metal projections may also be used to help route electric charges more rapidly away from certain areas in the array or work to more rapidly move electric charges to the metal layer (like electrical traces across the face of the pixel array, but made of closely spaced metal projections instead).

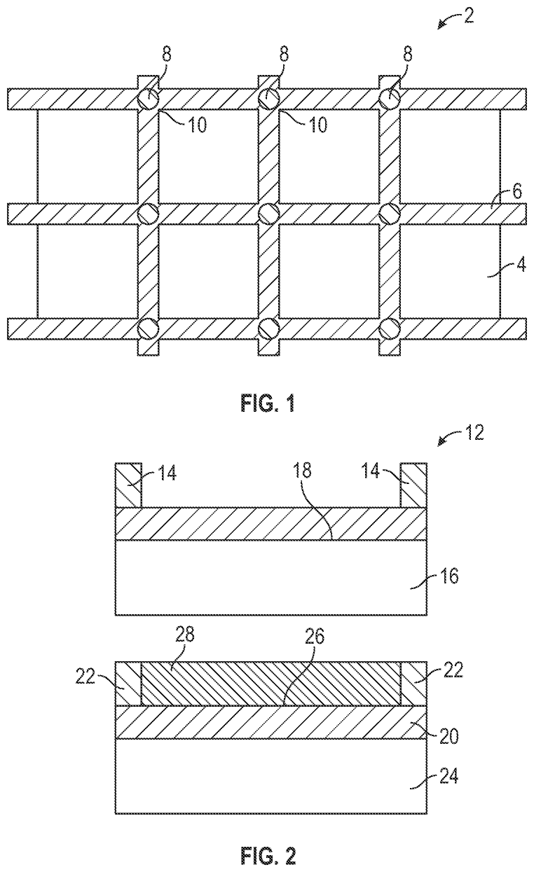

Referring to FIG. 2, a first implementation of a metal grid 12 is illustrated that includes two metal projections 14 coupled thereto. In the cross sectional view in this implementation, the metal grid 12 is coupled to a portion of the photodiode array 16. In this implementation, the side 18 of the photodiode array 16 that the metal layer 12 is coupled to is the back side of the photodiode array 16, or the side opposite the side which receives electromagnetic radiation and may include microlenses, a color filter array, or faces an optically transmissive cover. As illustrated in this implementation, the two metal projections 14 are free standing, or in other words, they extend from the metal layer 12 without being surrounded by any other supporting/encapsulating material. In this implementation, the use of the metal projections 14 increases the total surface area of the metal layer 12 and also creates focused points on the metal layer 12 which aid in the collection/gettering of static electric charges adjacent to the metal layer 12 to route them into the material of the metal layer 12.

Referring to FIG. 2 again, a second implementation of a metal grid 20 is illustrated that includes metal projections 22 extending therefrom. This metal grid 20 is coupled to the back side 26 of the photodiode array 24 similar to the previously described implementation. In this implementation, the metal projections 22 are located in a layer of passivation material 28. Since the back side passivation material is where the storage of electric charges has been observed to occur after an ESD event, the ability of the metal projections 22 to directly contact the layer of passivation material 28 on the back side 26 of the photodiode array 24 may assist with the collection/gettering of the electric charge into the metal projections 22 and then down into the metal grid 20. While in this implementation the metal projections 22 are illustrated as passing completely through the material of the passivation material 28, in other implementations, the metal projections 22 may extend only partially into the thickness of the layer of passivation material 28 leaving the ends covered by the layer of passivation material.

Because the metal projections 14, 22 stand free or are located in the layer of passivation material 28 only, the metal projections 14, 22 do not participate in the process of gathering photon generated charge in the silicon substrate/photodiode array 16, 24 itself. Thus the function of the metal projections 14, 22 is to assist with handling of electric charge in the form of static charge or stored charge from an ESD event rather than providing/collecting any electrical charge used by the photodiodes/image sensor to form an image resulting from electromagnetic irradiation. In the various image sensor implementations disclosed herein, a wide range of wavelengths of electromagnetic radiation may be employed, such as, by non-limiting example, infrared light, ultraviolet light, visible light, microwave, radio wave, x-ray, or any other electromagnetic radiation type to which the array of photodiodes is responsive.

Referring to FIG. 2, the free standing metal projections 14 could be formed in a subtractive process where a patterned layer is formed on a metal layer. The patterned layer may be formed using a photolithography process involving a patterned photoresist or by using a hard mask process where a photolithography/etch process is used to etch an oxide/nitride pattern which is subsequently used in etching the metal layer away except for where the pattern is present leaving a set of metal pillars that form the metal projections 14. In this method implementation, the metal etching may take place using a dry or wet etching process. In various implementations, where a patterned photoresist is used, the photoresist will typically be removed following etching of the metal projections 14. In various implementations, the hard mask material may be left on the metal projections 14 or may be removed depending the desired electrical conductivity desired for the metal projections 14. In various method and structure implementations, the metal material used for the metal projections 14 may be the same as the metal material of the metal layer 12; in others, the metal materials used for the metal projections 14 and the metal layer 12 may be different.

In another method implementation, a damascene or additive process may be employed to form the metal projections where a layer of oxide, nitride, or passivation material is deposited over the metal layer and then has openings formed therein into which metal is deposited using a chemical vapor deposition process (such as when tungsten is employed) or using an electroplating process (such as when copper is employed). A chemical mechanical planarization (CMP) process may then be employed to bring the deposited metal down to the surface of the layer of oxide, nitride, or passivation material and leave the top surfaces of the metal projections electrically isolated from each other. The remaining oxide, nitride, or passivation material is then etched away to leave the free standing metal projections 14.

The foregoing damascene process may also employed to form the second implementation illustrated FIG. 2, with the difference that the passivation material 28 is not etched away, leaving the metal projections 22 within the passivation material 28 as illustrated. In some implementations, a damascene process may be employed to form the metal layer 20 and the metal projections 22 in two different steps. A wide variety of method implementations for forming the metal projections may be constructed using the principles disclosed herein.

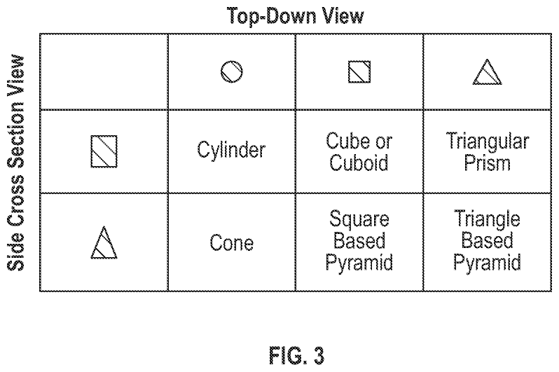

Referring to FIG. 3, a diagram of various possible shapes for metal projections is illustrated. In the left column, the side cross section view shows a prism (constant or substantially constant cross section for the metal projection) and a cone (tapering cross section for the metal projection). While not illustrated in the side cross section view, conical frustum shapes may also be employed for the side cross sections of various metal projections in various implementations. Three non-limiting examples of cross sectional shapes for the metal projections are illustrated in the diagram of FIG. 3, a circle, square, and triangle. Where the cross section is a circle and the side cross section view is a prism, the resulting shape would be cylinder. Where the cross section is a square/rectangle and the side cross section view is a prism, the resulting shape would be cube/cuboid. Where the cross section is a triangle and the side cross section view is a prism, the resulting shape is a triangular prism.

Similarly, where the shape of the cross section of the base of the cone is a circle or ellipsoid, the resulting shape of the metal projection is a cone. Where the shape of the cross section is a square or rectangle, then a square based pyramid results. Where the shape of the cross section is a triangle, the resulting shape is a triangle-based pyramid.

While the side cross sectional views in FIG. 3 are illustrated as having straight sides, in various implementations, the sides may be curved or rounded forming a prism with a curved or rounded side surface. Furthermore, while a circle/ellipsoid, square/rectangle, and triangle are illustrated, the cross sectional shape of the metal projection may take any of a wide variety of shapes including, by non-limiting example, a parallelogram, a pentagon, a hexagon, an octagon, or any other closed shape. In this way, a prism or cone of any of a wide variety of cross sectional shapes may be formed using the principles disclosed in this document.

In places where the description above refers to particular implementations of image sensor charge direction structures and methods and implementing components, sub-components, methods and sub-methods, it should be readily apparent that a number of modifications may be made without departing from the spirit thereof and that these implementations, implementing components, sub-components, methods and sub-methods may be applied to other image sensor charge direction structures and methods.

What is claimed is:

1. A static charge handling system comprising:
an array of photodiodes;
a metal grid coupled to the array of photodiodes; and
a set of metal projections extending away from the metal grid, the set of metal projections configured to direct charge from one of electrostatic discharge or static charge into the metal grid.

2. The system of claim 1, wherein the set of metal projections are located on a side of the metal grid opposite the array of photodiodes.

3. The system of claim 1, wherein the set of metal projections are each located at a set of intersections of the metal grid.

4. The system of claim 1, wherein the set of metal projections are in a layer of passivation material coupled to the metal grid.

5. The system of claim 1, wherein the array of photodiodes is comprised in a backside illumination sensor.

6. The system of claim 1, wherein the set of metal projections comprise one of a rectangular prism, a cylinder, or a triangular prism.

7. The system of claim 1, wherein the set of metal projections comprise one of a square based cone, a triangle based cone, a cone, or a conical frustum.

8. A static charge handling system comprising:
an array of photodiodes;
a metal grid coupled on a first side of the array of photodiodes; and
a set of metal projections coupled on a side of the metal grid opposite the first side of the array of photodiodes and extending away from the metal grid.

9. The system of claim 8, wherein the set of metal projections are each located at a set of intersections of the metal grid.

10. The system of claim 8, wherein the set of metal projections are each located along the metal grid.

11. The system of claim 8, wherein the set of metal projections are in a layer of passivation material coupled to the side of the metal grid opposite the first side of the array of photodiodes.

12. The system of claim 8, wherein the array of photodiodes are comprised in a backside illumination sensor.

13. The system of claim 8, wherein the set of metal projections comprise one of a rectangular prism, a cylinder, or a triangular prism.

14. The system of claim 8, wherein the set of metal projections comprise one of a square based cone, a triangle based cone, a cone, or a conical frustum.

15. A method of handing charge comprising:
providing an array of photodiodes with a first side to which a metal grid is coupled and a set of metal projections coupled to the metal grid on a side of the metal grid opposite the first side of the array of photodiodes and extending away from the metal grid;
receiving electric charge into the set of metal projections; and
directing the electric charge into the metal grid.

16. The method of claim 15, further comprising where the metal grid is grounded and directing the electric charge to ground using the metal grid.

17. The method of claim 15, wherein receiving electric charge further comprises receiving electric charge from a passivation layer.

18. The method of claim 15, wherein the set of metal projections is formed in a passivation layer.

19. The method of claim 15, wherein the electric charge is from one of electrostatic discharge events or static electricity.

20. The method of claim 15, wherein the array of photodiodes is comprised in a backside illumination sensor.
